(19) United States
(12) Patent Application Publication
(10) Pub. No.: US 2012/0189131 A1
(43) Pub. Date: Jul. 26, 2012

(54) LOW-PITCHED SOUND ENHANCEMENT PROCESSING APPARATUS, SPEAKER SYSTEM AND SOUND EFFECTS APPARATUS AND PROCESSES

(75) Inventors: Masato Ueno, Hamamatsu City (JP); Mitsuhiro Umeta, Hamamatsu City (JP); Yoriko Sasamori, Hamamatsu City (JP)

(73) Assignee: Roland Corporation

(21) Appl. No.: 13/290,365

(22) Filed: Nov. 7, 2011

(30) Foreign Application Priority Data
Jan. 24, 2011 (JP) 2011-012313

(51) Int. Cl. H03G 3/00

(52) U.S. Cl. 381/61

(57) ABSTRACT

Musical sound signals in at least one frequency band in a low band range are enhanced by a low-pitched sound enhancement processing device. Musical sound signals greater than a predetermined level are compressed by a compression device, such that the level in a low band range would not become excessively large, while musical sound signals with a lower level are enhanced by an enhancement device to be outputted with sufficient sound pressure. Also, the input/output level ratio is determined based on the level of inputted musical sound signals, to prevent the output level from becoming smaller than the input level.

### CROSS-REFERENCE TO RELATED PATENT APPLICATIONS

Japan Priority Application No. 2011-012313, filed Jan. 24, 2011, including the specification, drawings, claims and abstract, is incorporated herein by reference in its entirety.

### FIELD OF THE INVENTION

Embodiments of the invention relate to a low-pitched sound enhancement processing apparatus, a speaker system for musical instruments, a sound effects apparatus and processes for making and using the same, and in particular embodiments, to a low-pitched sound enhancement processing apparatus, a speaker system for musical instruments, and a sound effects apparatus and processes which can favorably enhance low-pitched sounds of a musical instrument capable of generating sounds in a low band range, and output the same regardless of the magnitude of an input signal level.

### BACKGROUND

Amplifiers for connecting to a string musical instrument capable of generating sounds in a low band range (for example, a bass) must be able to output sounds in the low band range with sufficient sound pressure. Common responses include increasing the sound pressure of sounds in a low band range by enlarging the aperture of the speaker, or raising the level of signals in a low band range using an equalizer, or the like. Alternatively, a device as described in Laid-open patent application 2006-129199 is configured to increase the sound pressure of sounds in a low band range by using a speaker system having a bass-reflex type cabinet.

However, the use of a speaker with a large aperture can increase the cost of the device. Also, the use of a cabinet can increase the size of the device, which can make handling (including transportation or the like) more inconvenient.

Also, the lower the band range, the greater the vibration amplitude of the speaker's vibration plate. Therefore, if the level of signals in a low band range is raised too high by an equalizer, vibration of the vibration plate may exceed the speaker's allowable range, which may generate abnormal sounds. On the other hand, power amplifiers typically have maximum permissible input levels such that, when the signal'level inputted in a power amplifier exceeds the maximum permissible input level, the output of the power amplifier would have distortion. Moreover, a bass-reflex type speaker system can produce a whistling sound, generated by the air moving in and out of an opening section (port) of the cabinet. The whistling sound tends to abruptly increase when the vibration of the speaker's vibration plate becomes sufficiently large. Accordingly, there have been limitations to the level of signals in a low band range to be inputted in a power amplifier or outputted from a speaker.

### SUMMARY OF THE DISCLOSURE

Embodiments of the present invention provide a low-pitched sound enhancement processing apparatus, a speaker system for musical instruments, a sound effects apparatus and processes for making and using the same, which can favorably enhance low-pitched sounds played by a musical instrument capable of generating sounds in a low band range (for example, a bass).

A low-pitched sound enhancement processing apparatus according to an embodiment of the invention, is provided an input musical sound signal based on performance of a string musical instrument capable of generating sounds in a low band range (for example, a bass). The input musical sound signal (i.e., an input signal) or a musical sound signal that has been generated by adding a predetermined effect to the input musical sound signal, is divided into a plurality of frequency bands by a band divider device. A musical sound signal in at least one of the frequency bands belonging to a low band range among the divided frequency bands is enhanced by a low-pitched sound enhancement processing device. The low-pitched sound enhancement processing device has a compression device that compresses a musical sound signal that is higher than a predetermined level with a predetermined compression characteristic, and an enhancement device that is provided in a preceding stage and/or a succeeding stage of the compression device, enhances the musical sound signal and outputs the same. The musical sound signal inputted in the low-pitched sound enhancement processing device is enhanced through compression by the compression device and enhancement by the enhancement device, and then outputted. In other words, musical sound signals greater than the predetermined level are compressed by the compression device, such that the input level in a low band range to a power amplifier located in a succeeding stage of the low-pitched sound enhancement processing device would not become excessively large. However, musical sound signals with a smaller level can be outputted with sufficient sound pressure as they are enhanced by the enhancement device.

On the other hand, as the compression device of the low-pitched sound enhancement processing device is configured to compress and then output a musical sound signal higher than a predetermined level, an inconvenience may occur in that, when the input level becomes higher by a certain level, the output level from the low-pitched sound enhancement processing device could become even lower than the input level.

If signals at a lower level than the input level are outputted from the low-pitched sound enhancement processing device, the output sound in a low band range can lack sufficient sound pressure. Also, there could be an inconvenience in that, if the level of musical sound signals inputted from the input device is low, and the level of musical sound signals inputted in the low-pitched sound enhancement processing device is always lower than a predetermined level, sounds in a low band range may be excessively enhanced. However, in a low-pitched sound enhancement processing apparatus in accordance with embodiments of the present invention, compression by the compression device and/or enhancement by the enhancement device are controlled by the control device in a manner that the input/output level ratio of the apparatus is decided based on the input level of musical sound signals inputted in the low-pitched sound enhancement processing device. Therefore, it becomes possible to output sound at an output level corresponding to an input level, and therefore the inconvenience described above can be eliminated.

Therefore, a low-pitched sound enhancement processing apparatus according to embodiments of the invention, can favorably enhance and output low-pitched sounds played by a musical instrument capable of generating sounds in a low band range, regardless of the magnitude of the level of input signals.

In another example of a low-pitched sound enhancement processing apparatus according to the above-described embodiments, the control device may control compression by the compression device and/or enhancement by the enhancement device, such that the input/output level ratio provided by the low-pitched sound enhancement processing device becomes greater (in other words, enhanced more) with an elevation in the input level of musical sound signals inputted to the low-pitched sound enhancement processing device. Therefore, although musical sound signals higher than a predetermined level inputted in the low-pitched sound enhancement processing device are configured to be compressed and outputted, the inputted musical sound signals can be enhanced and outputted regardless of their input level. For example, even when the performer intentionally adjusts, for the sake of performance, the input level of musical sound signals inputted from the input device to be greater, thereby distorting the sounds, the output level from the low-pitched sound enhancement processing device can be prevented from becoming lower than the input level, and sounds in a low band range can be outputted with sufficient sound pressure. Therefore, a low-pitched sound enhancement processing apparatus according to an embodiment of the invention can favorably enhance and output low-pitched sounds played by a musical instrument capable of generating sounds in a low band range, according to the performer's intention.

In another example of a low-pitched sound enhancement processing apparatus according to any of the above-described embodiments, the control device may control the threshold value at the compression device to have a level greater than a predetermined level, continuously or in stepwise, along with an elevation in the input level of musical sound signals inputted in the low-pitched sound enhancement processing device. Under such control, the input/output level ratio of the low-pitched sound enhancement processing device becomes greater based on the input level of musical sound signals inputted in the low-pitched sound enhancement processing device. Therefore, although embodiments are configured such that musical sound signals higher than a predetermined level (threshold value) inputted in the low-pitched sound enhancement processing device are compressed and outputted, in further examples the inputted musical sound signals can be enhanced and outputted regardless of their input level. In addition, as the threshold value at which the compression device performs compression is changed, deterioration of the sound quality can be prevented. Therefore, a low-pitched sound enhancement processing apparatus according to embodiments of the invention can favorably enhance and output low-pitched sounds played by a musical instrument capable of generating sounds in a low band range, according to the performer's intention.

In another example of a low-pitched sound enhancement processing apparatus according to any of the above-described embodiments, the input level of musical sound signals inputted in the low-pitched sound enhancement processing device may be adjusted by an input level adjusting device, based on the value of a gain set by operation of a gain setting device. The control device may control compression by the compression device and/or enhancement by the enhancement device, based on the value of a gain set by the gain setting device, such that the input/output level ratio provided by the low-pitched sound enhancement processing device becomes greater, continuously or in stepwise, with an elevation in the input level of musical sound signals inputted in the low-pitched sound enhancement processing device. Therefore, even when the performer operates the gain adjusting device in order to distort the output sound as an intended performance operation, the output level from the low-pitched sound enhancement processing device can be prevented from becoming smaller than the input level, and outputs can be provided according to the intended performance, such that low-pitched sounds played by a musical instrument capable of generating sounds in a low band range can be favorably enhanced and outputted according to the performer's intention.

In another example of a low-pitched sound enhancement processing apparatus according to any of the above-described embodiments, time-dependent changes in the input level of a musical sound signal inputted in the low-pitched sound enhancement processing device may be monitored by a monitoring device. The control device may control compression by the compression device and/or enhancement by the enhancement device, based on the time-dependent changes in the monitored input level, such that the input/output level ratio provided by the low-pitched sound enhancement processing device becomes greater, continuously or in stepwise, with an elevation in the input level of musical sound signals inputted in the low-pitched sound enhancement processing device. Therefore, low-pitched sounds played by a musical instrument capable of generating sounds in a low band range can be favorably enhanced and outputted regardless of the magnitude of the level of input signal.

In another example of a low-pitched sound enhancement processing apparatus according to any of the above-described embodiments, the string musical instrument (a string musical instrument capable of generating sounds in a low band range) that inputs musical sound signals in the input device may be a bass. This is effective in that performance sounds by the bass performance can be favorably enhanced and outputted.

In another example embodiment, a speaker system is equipped with of a low-pitched sound enhancement processing apparatus according to any of the above-described embodiments, such that the speaker system can achieve effects as described above. In such speaker system embodiments, low-pitched sounds favorably enhanced by the low-pitched sound enhancement processing apparatus of any of the above example embodiments can be emanated from a speaker through a power amplifier.

In another example, a speaker system according to the above-mentioned embodiment may be configured as a bass-reflex type speaker having a cabinet provided with an opening section for bass reflex, through which the interior space of the cabinet communicates with the outside. The frequency band processed by the low-pitched sound enhancement processing device is a frequency band including the resonance frequency of the opening section for bass-reflex, such that the signal level in the frequency band can be controlled, and generation of whistling sound can be suppressed.

In another example, a speaker system according to the above-mentioned embodiments, one or a plurality of effect devices (each capable of having a pass gain greater than 1 for adding an effect to a musical sound signal) is/are provided in a preceding stage of the low-pitched sound enhancement processing apparatus. Accordingly, even when an effect to be obtained when the pass gain that is set greater than 1 is added to a musical sound signal, low-pitched sounds that are favorably enhanced by the low-pitched sound enhancement processing apparatus can be outputted from the speaker.

In another example embodiment, a low-pitched sound enhancement processing apparatus according to any of the above-described embodiments is equipped with a sound effect device. Also, one or a plurality of effect devices each capable of having a pass gain greater than I for adding an effect to a musical sound signal is provided in a preceding stage of the low-pitched sound enhancement processing apparatus, such that, even when an effect to be obtained by the pass gain set greater than 1 is added to a musical sound signal, low-pitched sounds that are favorably enhanced by the low-pitched sound enhancement processing apparatus can be outputted.

### BRIEF DESCRIPTION OF THE DRAWINGS

FIG. 1(a) is a schematic front view of a speaker system that is a low-pitched sound enhancement processing apparatus in accordance with an embodiment of the invention.

FIG. 1(b) is a schematic cross-sectional view of the speaker system taken along lines Ib-Ib of FIG. 1(a).

FIG. 2 is a front view of an operation panel of the speaker system of FIG. 1(a).

FIG. 3(a) is a block diagram of an electrical configuration of a control device of the speaker system of FIG. 1(a).

FIG. 3(b) is a schematic diagram of a process flow, using functional blocks, which are executed by a DSP of the control device of FIG. 3(a).

FIG. 4(a) is a functional block diagram schematically showing a process flow executed by a Low_Boost block.

FIG. 4(b) is a graph representing an example of frequency characteristics of a channel divider in FIG. 4(a).

FIG. 5 is a functional block diagram schematically showing a process flow executed by a low-pitched sound enhancement unit.

FIG. 6(a) is a graph representing input/output characteristics of a compressor.

FIG. 6(b) is a graph representing input/output characteristics of a low-pitched sound enhancement section of FIG. 5 in a normal setting.

FIG. 6(c) is a graph representing input/output characteristics of the low-pitched sound enhancement section of FIG. 5 in a high gain setting.

FIG. 7 is a flow chart of a parameter setting process executed by the CPU in FIG>3.

FIG. 8 is a functional block diagram schematically showing a process flow executed by a low-pitched sound enhancement apparatus in accordance with a second embodiment.

FIG. 9(a)-9(c) are graphs representing input/output characteristics of low-pitched sound enhancement sections in accordance with modified examples.

FIG. 10 is a functional block diagram schematically showing a process flow executed by a low-pitched sound enhancement processing apparatus in accordance with a modified example of the second embodiment.

### DETAILED DESCRIPTION

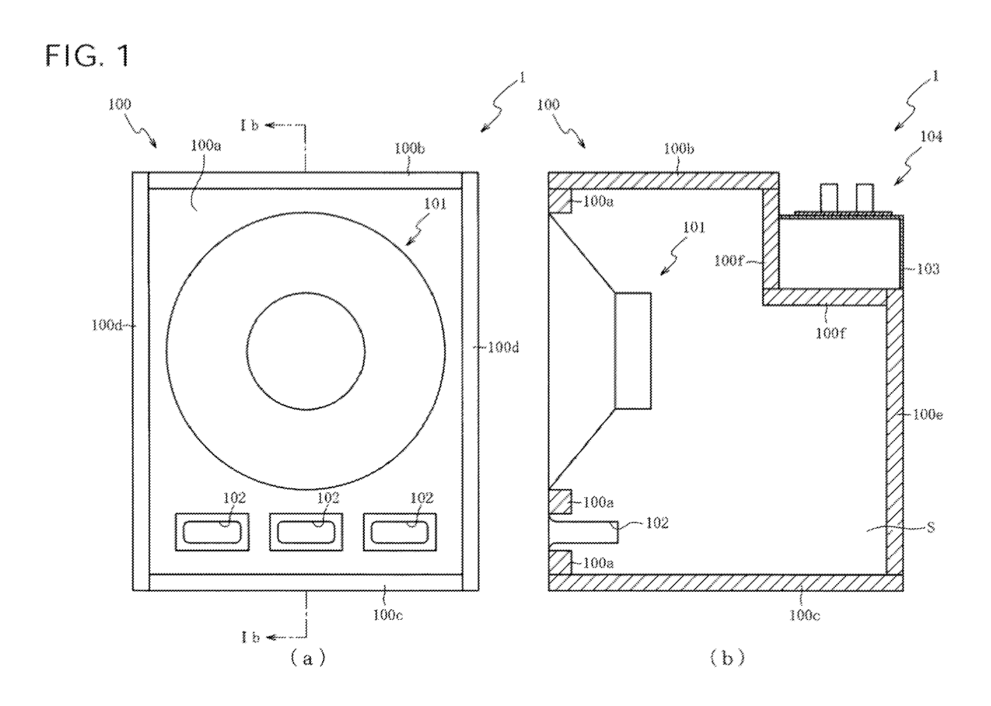

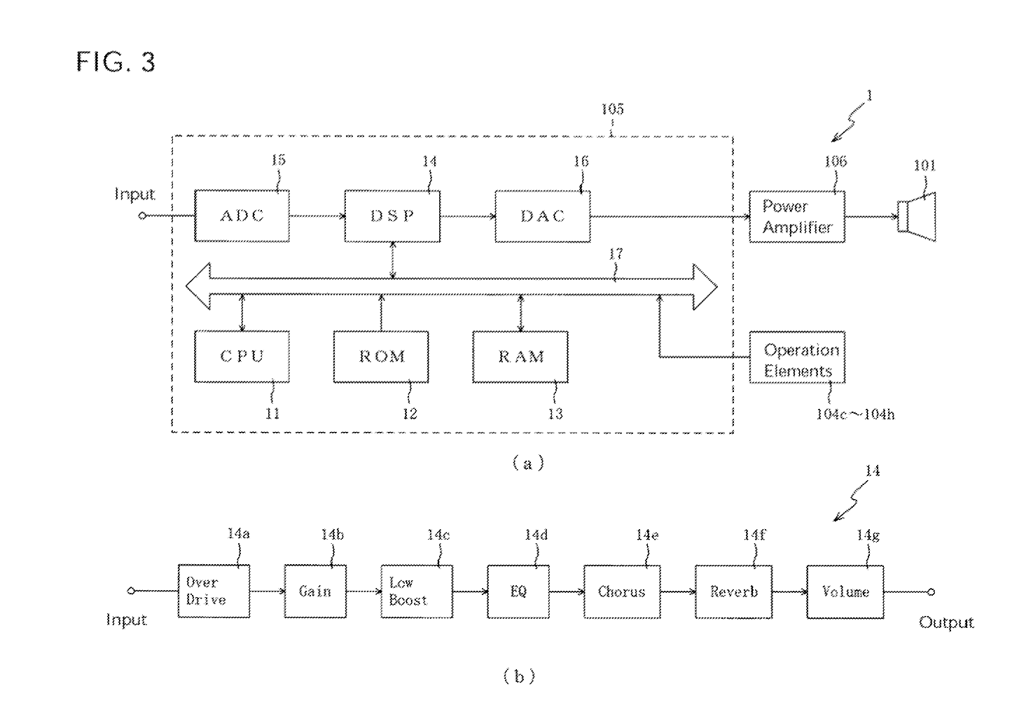

Embodiments of the invention are described below with reference to the accompanying drawings. FIG. 1(a) is a schematic front view of a speaker system 1 having a control device 105 mounted thereon, where the speaker system 1 is a low-pitched sound enhancement processing apparatus in accordance with an embodiment of the invention. FIG. 1(b) is a schematic side cross-sectional view of the speaker system 1 taken along lines Ib-Ib of FIG. 1(a). It is noted that, FIG. 1(b) does not include illustrations of certain parts of the system, such as, a control device 105 and a power amplifier 106 (which are described below-with reference to FIG. 3), wiring cables and the like.

The speaker system 1 in accordance with an example embodiment is configured as a speaker system for a bass. The speaker system 1 is configured to have the control device 105 provided with a function such as that of Low_Boost block 14c (see FIG. 3), such that sounds in a low band range (for example, a range below 100 Hz) can be favorably enhanced and outputted.

The speaker system 1 includes a cabinet 100, a speaker 101, three bass-reflex ports 102, a chassis 103 and a control panel 104. The speaker system 1 in accordance with this example embodiment is a bass-reflex type speaker system having bass-reflex ports 102 (i.e., a bass-reflex type speaker).

The cabinet 100 includes a front panel 100a that defines a sound emanating surface (a front face) of the speaker 101, an upper panel 100b that defines an upper face, a bottom panel 100c that defines a bottom face, two side panels 100d that defines two side faces, a rear panel 100e that defines a rear face, and a partition panel 100f for forming a step in the upper panel 100b on the side of the rear panel 100e. The cabinet 100 has an internal space S that is surrounded by these panels 100a-100f. In further embodiments, a mesh cover may be provided at the front surface side of the front panel 100a. The bass-reflex ports 102 are opening sections provided below the speaker 101 in the front panel 100a. In accordance with the present embodiment, each bass reflex port 102 includes a tubular member that is attached at an opening provided in the front panel 100a. Each tubular member has end an portion on the side of the front panel 100a that is flared outward. Alternatively, tubular members that do not have flared end portions may be used in the bass-reflex ports. Also, openings provided in the front panel 100a may be used as the buss-reflex ports, without including tubular members.

The chassis 103 is a member for retaining a substrate on which a power amplifier 106 and a control device 105 (see FIG. 3) are mounted. The partition panel 100f of the cabinet 100 forms a stepped portion that provides a surface facing generally in parallel with the bottom panel 100c and another surface facing generally in parallel with the front panel 100a

The operation panel 104 is provided on the chassis 103 and comprises a panel on which manual operation elements are provided, including, for example, a power supply button for powering on the speaker system 1 and a group of operation elements that are selectively operated by the user for adjusting sounds.

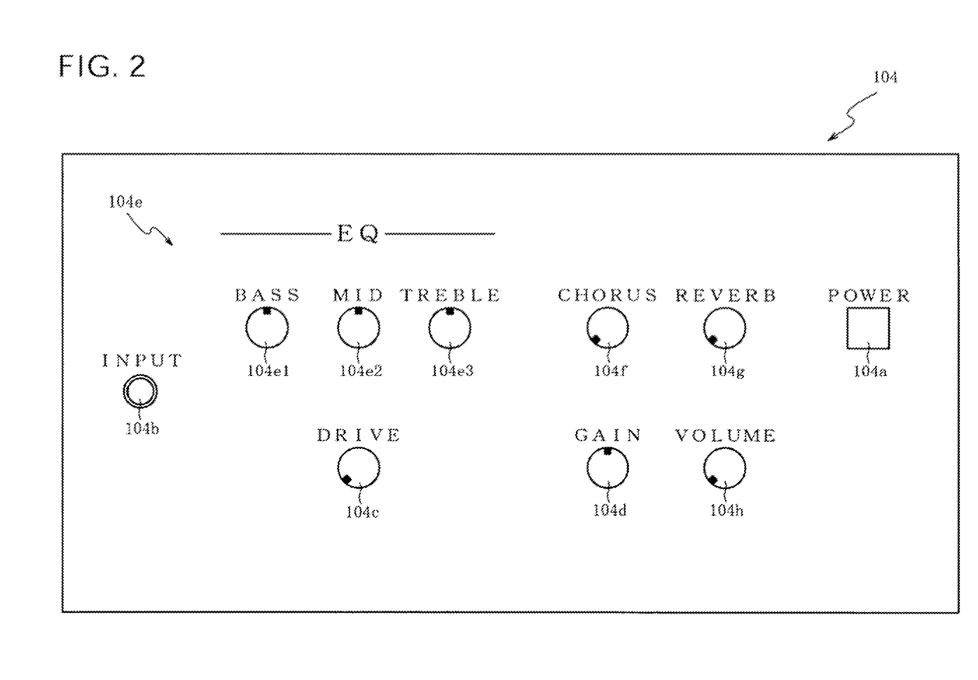

FIG. 2 is a front view of the operation panel 104 according to an example embodiment of the invention. As shown in FIG. 2, the operation panel 104 is provided with a power supply button (POWER) 104a for switching between power on and power off of the speaker system 1, an input terminal (INPUT) 104b for inserting an output terminal of a bass, a drive operation element (DRIVE) 104c, a gain operation element (GAIN) 104d, an equalizer operation element (EQ) 104e, a chorus operation element (CHORUS) 104f, a reverb operation element (REVERB) 104a and a volume operation element (VOLUME) 104h.

In an example embodiment, the drive operation element 104c is a dial operation element. The drive operation element 104c is configured to adjust (set) the degree of an effect that simulates a phenomenon in which distortion is generated when a high level signal is inputted in a preamplifier of an analog amplifier (hereafter, this effect is referred to as the “overdrive effect”). When the drive operation element 104c is at a position where it cannot be further turned counterclockwise, the gain value of an Over_Drive block 14a (see FIG. 3(b)) described below is set at 1, and the amount (the degree) of the overdrive effect is set to zero (in other words, the overdrive effect is not applied). The more the drive operation element 104c is turned clockwise, the greater the setting of the gain value of the Over_Drive block 14a (for example, greater than 1), whereby the overdrive effect is applied in a greater degree.

In an example embodiment, the gain operation element 104d is also a dial operation element. The gain operation element 104 is provided for simulating a phenomenon that takes place when the gain of the preamplifier of the analog amplifier is adjusted. The more that the gain operation element 104 is turned clockwise, the greater the gain value can be made of a Gain block 14b (see FIG. 3(b)) described below. In the speaker system 1 in accordance with an example embodiment, when the gain operation element 104b is located at a predetermined position (for example, the center of its rotation range), the gain is set at a reference level (for example, the gain value=1). As the gain operation element 104b is turned counterclockwise further from the predetermined position, the gain value of the Gain block 14b can be made smaller; and as it is turned clockwise further from the predetermined position, the gain value of the Gain block 14b can be made greater.

In a speaker system 1 according to an example embodiment of the invention, contents of the compression process applied to signals to be executed in a Low_Boost block 14c (see FIG. 3) are changed according to the gain value corresponding to an operated position of the drive operation element 104c and the gain value corresponding to an operated position of the gain operation element 104d. In this manner, the speaker system I is configured to enhance sounds in a low band range suitably for each of the cases when the product of the gain values set by the operation elements 104c and 104d is set at 1 or less, and when the product of these gain values is set greater than 1.

The equalizer operation element 104e in an example embodiment is a dial operation element. The equalizer operation element 104e is provided for setting the signal level in each range of a plurality of defined frequency ranges. The equalizer operation element 104e in accordance with an example embodiment includes a low band range dial (BASS) 104e1, a middle band range dial (MIDDLE) 104e2 and a high band range dial (TREBLE) 104e3. By turning each of the dials, the output level in each of the ranges can be adjusted.

The chorus operation element 104f in an example embodiment of the invention is a dial operation element. The chorus operation element 104f is provided for adjusting the degree of the chorus effect. When the chorus operation element 104f is at a position where it cannot be further rotated counterclockwise, the amount (the degree) of the chorus effect can be set to zero. The more the chorus operation element 104f is turned clockwise, the stronger the applied chorus effect.

The reverb operation element 104g in an example embodiment of the invention is a dial operation element. The reverb operation element 104g is provided for adjusting the degree of the reverb effect. When the reverb operation element 104g is at a position where it cannot be further rotated counterclockwise, the amount (the degree) of the reverb effect can be set to zero. The more the reverb operation element 104g is turned clockwise, the stronger the applied reverb effect.

The volume operation element 104h in an example embodiment of the invention is a dial operation element. The volume operation element 104h is provided for adjusting the volume level of sounds to be outputted from the speaker 101. When the volume operation element 104h is at a position where it cannot be further rotated counterclockwise, the level of sounds outputted from the speaker 101 can be set to zero. The more the volume operation element 104h is turned clockwise, the greater the level of emanated sounds.

An example of a configuration of the control device 105 for operating the speaker system 1 is described with reference to FIG. 3(a). In particular, FIG. 3(a) is a block diagram of an example of an electrical configuration of the control device 105 on the speaker system 1.

The control device 105 includes a CPU 11, a ROM 12, a RAM 13, a DSP 14, an analog-to-digital converter (ADC) 15, and a digital-to-analog converter (DAC) 16. Each of the units 11-14 except the ADC 15 and the DAC 16 are connected with each other through a bus line 17. The ADC 16 and the DAC 17 are connected to the DSP 14. Also, the bus line 17 is connected to the operation elements 104c-104h described above, such that settings made by the operation elements 104-104h are inputted in the control device 105.

Performance sound (musical sound signals) of a bass inputted to the input terminal 104b is inputted as an input signal in the ADC 15. The DAC 16 is connected to a power amplifier 106, and outputs a signal that has been processed by the control device 105 to the power amplifier 106. The signal output from the DAC 16 is amplified by the power amplifier 106, and outputted from the speaker 101.

The CPU 11 is a central control device that executes controls according to fixed values data and control programs stored in the ROM 12 and the RAM 13. The ROM 12 is a rewritable memory, and stores a control program that controls the CPU 11 and the DSP 14 to execute various processes, and fixed values data that is referred to by the CUP 11 when the control program 12a is executed.

The RAM 13 is a rewritable memory, and has a work area (not shown) for temporarily storing various kinds of data when the CPU 11 executes the control program.

The DSP 14 is an operation device for processing digital signals. For example, the DSP 14 executes a control for enhancing sound in a low band range of performance sound (an input signal) from a bass that is inputted to the input terminal 104b and digitized by the ADC 15.

FIG. 3(b) is a functional block diagram schematically showing an example of a flow of processes executed by the DSP 14. An input signal (a musical sound signal) is first supplied to an Over_Drive block 14a.

The Over_Drive block 14a raises the input/output level ratio (gain) for a passing signal and generates distortion therein, thus adding overdrive effects to the passing signal. The Over_Drive block 14a adds overdrive effects according to the amount of operation of the drive operation element 104c. For example, the more the amount of rotation of the drive operation element 104c, the greater the overdrive effects added by the Over_Drive block 14a. The signal that has passed through the Over_Drive block 14a (outputted from the Over_Drive block 14a) is supplied to a Gain block 14b.

The Gain block 14b simulates a phenomenon taking place when the input sensitivity (gain) at a preamplifier unit in an analog amplifier is adjusted, and outputs the passing signal in an input/output level ratio according to a value (gain value) set by the gain operation element 104d. Also, when the gain value set by the gain operation element 104d is greater than 1, the Gain block 14b raises the input/output level ratio for the passing signal and generates distortion therein. The signal that has passed through the Gain block 14b (outputted from the Gain block 14b) is supplied to a Low_Boost block 14c.

The Low_Boost block 14c enhances signals in a low band range of the passing signal, as described below. The signal that has passed through the Low_Boost block 14c (outputted from Low_Boost block 14c) is supplied to an EQ block 14d in a succeeding stage.

The EQ block 14d raises or lowers the signal level of each of the ranges (the low band range, the middle band range, and the high band range) in the passing signal, according to the positions of the corresponding equalizer operation elements 104e (104e1-104e3), respectively. The signal that has passed through the EQ block 14d (outputted from the EQ block 14d) is supplied to a Chorus block 14e. The Chorus block 14e adds chorus effects to the passing signal, according to the amount of operation of the chorus operation element 104f. The signal that has passed through the Chorus block 14e (outputted from the Chorus block 14e) is supplied to a Reverb block 14f.

The Reverb block 14f adds reverb effects to the passing signal, according to the amount of operation of the reverb operation element 104g. The signal that has passed through the Reverb block 14f (outputted from the Reverb block 140 is supplied to a Volume block 14g in a succeeding stage.

The Volume block 14g controls the sound level of the passing signal according to the position of the volume operation element 104h, thus adjusting the output level (sound volume level) of sounds to be outputted from the speaker 101.

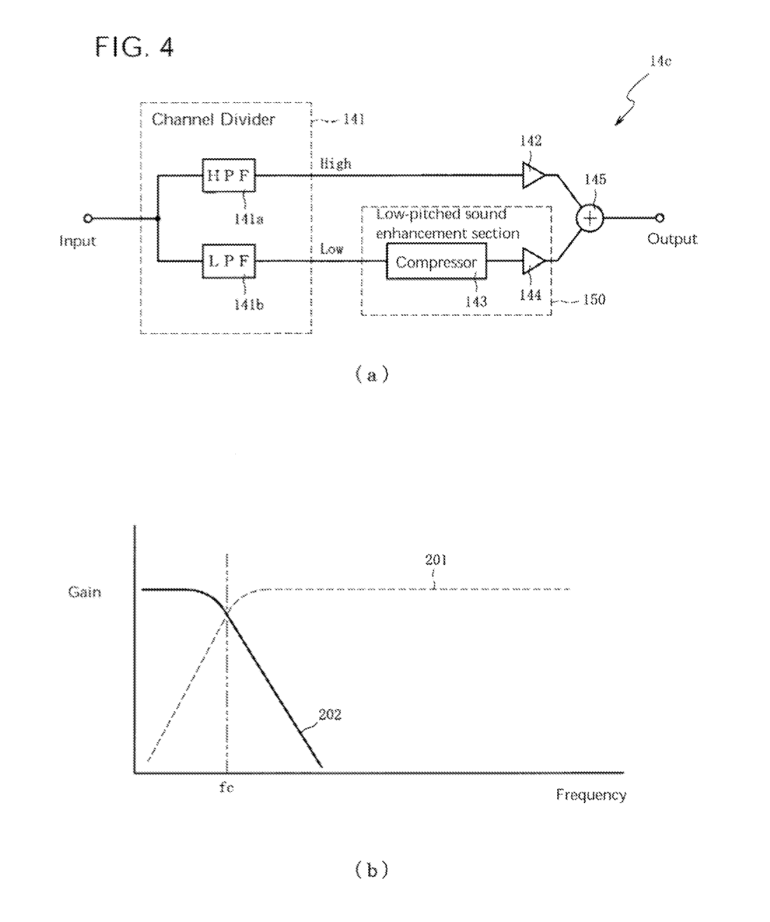

FIG. 4(a) is a functional block diagram schematically showing an example flow of processes executed by the Low_Boost block 14c described above. An input signal inputted to the Low_Boost block 14c is supplied to a channel divider 141. The channel divider 141 includes a high pass filter (HPF) 141a and a low pass filter (LPS) 141b, and divides the input signal into two channels, i.e., a signal (High) that is outputted from the high pass filter 141a and a signal (Low) that is outputted from the low pass filter 141b.

FIG. 4(b) is a graph representing one example of frequency characteristics of the channel divider 141. The horizontal axis of the graph represents frequency, and the vertical axis represents gains of signals passing through the channel divider 141. In the graph, a line 201 shown by a dotted line indicates frequency characteristics of a signal passing through the high pass filter 141a, and a line 202 shown by a sold line indicates frequency characteristics of a signal passing through the low pass filter 141b. A cut-off frequency fc of each of the filters 141a and 141b can be set independently from each other, and set to a predetermined value at the time of manufacture. As shown in FIG. 4(b), the cut-off frequency fc of each of the filters 141a and 141b may be set at the same value, such that an input signal can be divided into a signal above the cut-off frequency Fc and a signal below the cut-off frequency fc. In accordance with an example embodiment of the invention, the cut-off frequency fc of each of the filters 141a and 141b in the channel divider 141 is set at a frequency with which the signal passing through the low pass filter 141b becomes a signal in a low band range. In accordance with one example embodiment, the cut-off frequency fc is set at 100 Hz.

Referring back to FIG. 4(a), the signal that has passed through the high pass filter 141a in the channel divider 141 is supplied to a multiplier 142. The multiplier 142 multiplies the inputted signal (the signal that has passed through the high pass filter 141a) with the gain value set by the CPU 11, thus adjusting the level of the signal. It is noted that the gain value set at the multiplier 142 is determined, for example, at the time of manufacture, and may be set at 1 when there is no particular intention for enhancing sounds in a high band range. The signal having a level that has been adjusted by the multiplier 142 is supplied to an adder 145.

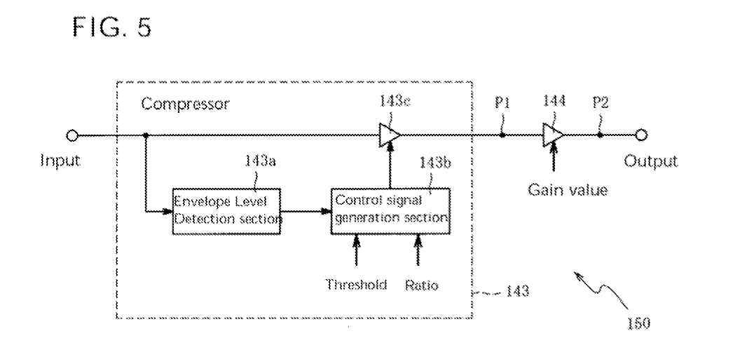

Meanwhile, the signal in a low band range that has passed through the low pass filter 141b in the channel divider 141 is supplied to the compressor 143. The compressor 143 compresses signals at a predetermined level (a predetermined envelope level) or higher and outputs the same, as described below with reference to FIG. 5. The signal that has passed through the compressor 143 (outputted from the compressor 143) is supplied to a multiplier 144. The multiplier 144 adjusts the level of the signal inputted from the compressor 143 with a gain value set by the CPU 11. The gain value set for the multiplier 144 is determined at the time of manufacture, and is set at a value greater than 1 for enhancing signals in a low band range. The signal having a level that has been adjusted by the multiplier 144 is supplied to the adder 145.

A low-pitched sound enhancement section 150 includes the compressor 143 and the multiplier 144 described above. The low-pitched sound enhancement section 150 in accordance with an example embodiment of the invention is configured such that its input/output level ratio (gain) is changed according to the product of a gain value of the Over_Drive block 14a (as set by operation of the drive operation element 104c) and a gain value of the Gain block 14b (as set by operation of the gain operation element 104d), as described below.

FIG. 5 is a functional block diagram, schematically showing the flow of processes executed by the low-pitched sound enhancement section 150. The signal inputted in the low-pitched sound enhancement section 150 passes through the compressor 143, then passes through the multiplier 144, and then is outputted.

The signal inputted in the compressor 143 is supplied to an envelope level detection section 143a and a multiplier 143c. The envelope detection section 143a detects an envelope level of the signal. More specifically, the envelope detection section 143a first obtains an absolute value of an instantaneous value of the input signal at a particular time and, if the obtained absolute value is greater than a previous envelope level stored in the RAM 13, stores the obtained absolute value in the RAM 13 as the value of an envelope level at that time (the RAM 13 is rewritten). On the other hand, if the obtained absolute value is smaller than that of a previous envelope level stored in the RAM 13, a value obtained by attenuating the previous envelop level by a predetermined time constant is stored in the RAM 13 as the value of an envelope level at that time. The envelope level detected (at that time) by the envelope level detection section 143a is supplied to a control signal generation section 143b.

The control signal generation section 143b generates a control signal for level control based on the envelope level inputted from the envelope level detection section 143a and the values of a threshold and of a ratio as set by the CPU 11.

The “threshold” is a threshold value for determining as to whether or not the compressor 143 should perform compression of the input signal. The compressor 143 performs compression of the signal when the level (input level) of the input signal is greater than the threshold value. In accordance with an example embodiment of the invention, the threshold value is a value set by the CPU 11 according to the product of a gain value corresponding to the operated position of the drive operation element 104c and a gain value corresponding to the operated position of the gain operation element 104d. More specifically, when the product of gain values set respectively by the operation elements 104c and 104d is 1 or less, a threshold value determined at the time of manufacture (hereafter referred to as a “standard threshold, value”) is set and; when the product of the two gain values is greater than 1, a value equal to “the standard threshold value multiplied by the product of the gain values set by the respective operation elements 104c and 104d is set. The “ratio” is a compression ratio used by the compressor 143 for performing compression of input signals. The set value of the ratio can be determined at the time of manufacture.

The control signal for level control generated by the control signal generation section 143b is supplied to the multiplier 143c. The multiplier 143c controls the level of the input signal with the control signal for level control supplied from the control signal generation section 143b. The signal outputted from the multiplier 143c (i.e., the signal outputted from the compressor 143) is supplied to the multiplier 144. As described above, the signal outputted from the compressor 143 and inputted in the multiplier 144 is multiplied by a gain value determined at the time of manufacture, such that its level is adjusted.

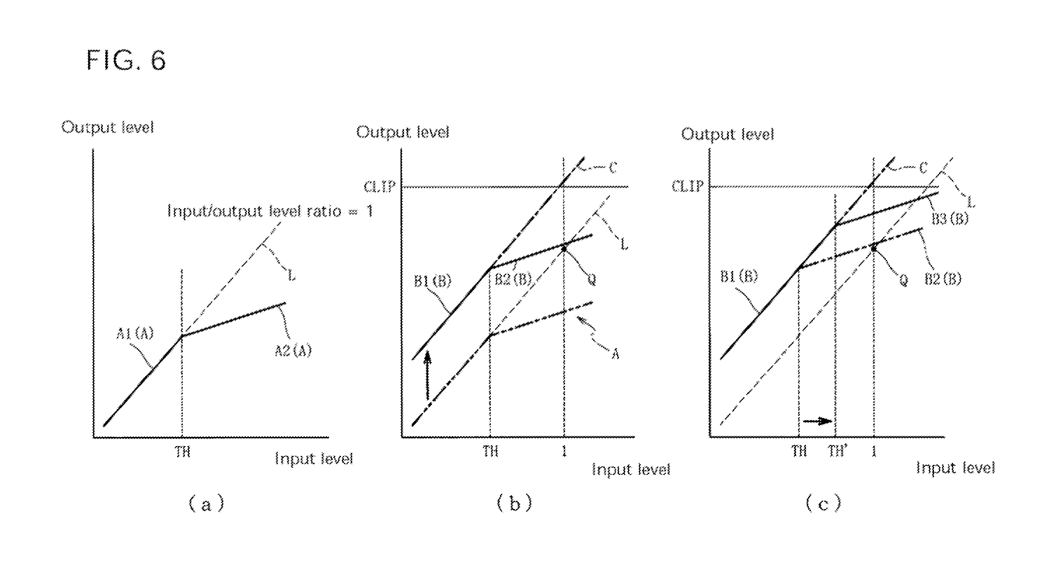

FIG. 6(a) is a graph representing input/output characteristics of the compressor 143 in accordance with an example embodiment of the invention. The horizontal axis of the graph represents in logarithmic scale input levels of signals inputted in the compressor 143, and the vertical axis of the graph represents in logarithmic scale output levels of signals outputted from the compressor 143 (i.e., signals at point P1 in FIG. 5). The “level” used in the following description is not the level of an instantaneous value, but is the level of an envelope. Also, a dotted line L is a linear line indicating that the input/output level ratio is 1. The input/output level ratio is greater than 1 in an area above the dotted line L, and the input/output level ratio is smaller than 1 in an area below the dotted line L.

The characteristics of the compressor 143 can be represented by a bent line A shown in a solid line. More specifically, when the input level is below the threshold value (TH), characteristics represented by a solid line A1 with the input/output level ratio being 1 are exhibited. When the input level exceeds TH, the level is compressed and characteristics represented by a solid line A2 are exhibited. It is noted that the inclination of the solid line A2 corresponds to the value of the ratio.

Next, referring to FIG. 6(b), input/output characteristics of the low-pitched sound enhancement section 150 composed of the compressor 143 described above and the amplifier 144 in the succeeding stage are described. FIG. 6 (b) is a graph representing input/output characteristics of the low-pitched sound enhancement section 150 in the normal setting. The “normal setting” corresponds to a case where, when the speaker system I is used with ordinary gain value settings, the product of gain values respectively set by the drive operation element 104c and the gain operation element 104d (in other words, the product of the two gain values) is 1 or less.

In the graph of FIG. 6(b), the horizontal axis represents, in logarithmic scale, input levels of signals inputted in the low-pitched sound enhancement section 150 (i.e., signals inputted in the compressor 143). The vertical axis of that graph represents, in logarithmic scale, output levels of signals outputted from the low-pitched sound enhancement section 150 (i.e., signals at point P2 in FIG. 5).

In the normal setting, the input/output characteristics of the low-pitched sound enhancement section 150 are represented by a bent line composed of a solid line B1 and a solid line B2. On the other hand, a bent line A shown in a two-dot-and-dash line, represents output levels from the compressor 143 (i.e., signal levels at point P1), and is the same as the bent line A shown in a solid line in FIG. 6 (a). In other words, the low-pitched sound enhancement section 150 has input/output characteristics in which the gain value inputted at the amplifier 144 is added to the output levels of the compressor 143. Specifically, the input/output characteristics of the low-pitched sound enhancement section 150 are represented by the solid line B1 when the input level is less than the threshold value (TH), and by the solid line B2 when the input level exceed TH.

In FIG. 6(b), “1” shown on the horizontal axis (input levels) indicates the maximum level of input signals presumed when the product of the gain values of the Over Drive block 14a and the Gain block 14b with respect to the low-pitched sound enhancement section 150 (i.e., the Low_Boost block 14c) is 1 or less. In the graph of FIG. 6(b), “CLIP” on the vertical axis (output levels) indicates the critical output level of the low-pitched sound enhancement section 150 (Low_Boost block 14c) at which distortion occurs at the power amplifier 106. When the output level from the low-pitched sound enhancement section 150 exceeds this level, distortion occurs at the power amplifier 106. A dot-and-dash line C is a linear line indicating input/output characteristics when the compressor 143 is removed, and corresponds to a conventional technology that uses an equalizer to raise the signal level in a low band range.

According to FIG. 6(b), the solid line B2 crosses over a point Q where the input/output level ratio is 1, at the input level being “1,” in other words, at the presumed maximum level of input signals. However, the solid line B2 passes below the critical output level (CLIP) where distortion occurs at the power amplifier 106. In other words, in the normal setting (when the speaker system 1 is used with ordinary gain value settings), signals inputted in the low-pitched sound enhancement section 150 that are below the “presumed maximum level of input signals” are raised, but the output level of the low-pitched sound enhancement section 150 would not exceed the critical output level at which distortion occurs at the power amplifier 106. Therefore, sounds in a low band range can be enhanced without causing distortion of the output from the power amplifier 106. On the other hand, as indicated by the dot-and-dash line C, if the signal level in a low band range is raised by an equalizer (according to conventional art), when a signal with high level is inputted, the output level may exceed the critical output level (CLIP) where distortion occurs at the power amplifier 106. Therefore, even though sounds in a low band range can be enhanced, distortion may be generated at the power amplifier 106.

Also, string musical instruments, such as, a bass, tend to have a short period in which the signal level is high and a relatively long period in which the signal level becomes lower due to attenuation. Accordingly, as shown in FIG. 6(b), the degree of enhancement when the signal level (input level) is high (i.e., the input/output level ratio indicated by the solid line B2) may be made smaller, and the degree of enhancement when the signal level is low (i.e., the input/output level ratio indicated by the solid line B I) may be made larger, such that the section of the relatively long period where the signal level is low can be accentuated. As a result, it is possible to cause an auditory sensation in which sounds in a low range are enhanced as a whole.

As described above, the input/output characteristics of the low-pitched sound enhancement section 150 at normal settings pass above the dotted line L at the presumed maximum level of input signals (see FIG. 6(b)). Accordingly, sounds in a low band range can be enhanced without causing distortion in the output of the power amplifier 106. However, if signals exceed the presumed maximum level of input signals, there may be cases where the output level becomes smaller than the input level. In the speaker system 1 in accordance with an example embodiment of the invention, the Over_Drive block 14a and the Gain block 14b (each of which can set the gain value higher than 1) are disposed in a preceding stage of the Low_Boost block 14c that includes the low-pitched sound enhancement section 150. Therefore; depending on the gain values set at blocks 14a and 14b, signals in a low band range outputted from the low-pitched sound enhancement section 150 may lack sufficient sound pressure.

In contrast, the speaker system 1 in accordance with example embodiments of the invention is configured such that, when a large gain value is set at the Over_Drive block 14a or the Gain block 14b, the threshold value set at the compressor 143 is changed, such that the sound pressure in a low band range can be favorably enhanced.

FIG. 6(c) is a graph representing input/output characteristics of the low-pitched sound enhancement section 150 in a high gain setting. In contrast to the “normal setting” described above, the “high gain setting” corresponds to a case where a large gain value is set at the Over_Drive block 14a or the Gain block 14b, in other words, the input/output level ratio (gain) of the blocks 14a and 14b is set high. In accordance with an example embodiment of the invention, a “high gain” gain setting corresponds to a case where the product of gain values respectively set at the drive operation element 104c and the gain operation element 104d is greater than 1. One example when the speaker system I is placed in the high gain setting may be when the user operates the drive operation element 104c and the gain operation element 104d in a manner to intentionally distort sounds. In the graph shown in FIG. 6(c), the horizontal axis represents, in logarithmic scale, input levels of signals inputted in the low-pitched sound enhancement section 150, and the vertical axis represents, in logarithmic scale, output levels of signals outputted from the low-pitched sound enhancement section 150.

As described above, when the product of gain values set by the respective operation elements 104c and 104d is greater than 1, the threshold value inputted in the control signal generation section 143b is calculated by the standard threshold value multiplied by the product of the gain values respectively set by the drive operation element 104c and the gain operation element 104d. In other words, the threshold value in the high gain setting is a value TH′ that is greater than TH (i.e., the standard threshold value). Due to the change of the threshold value from TH to TH′, the bent line B composed of two lines (a solid line B1 and a two-dot-and-dash line B2) with TH being a threshold value, is changed to the bent line B composed of two lines (a solid line B1 and a solid line B3) with TH′ being a threshold value.

Therefore, the input/output characteristics of the low-pitched sound enhancement section 150 in the high gain setting exhibit characteristics represented by the solid line B1 when the input level is below TH′, and exhibit characteristics represented by the solid line B3 when the input level exceeds TH′. Therefore, even for input signals with a level that is higher than the presumed maximum level of input signals, the level thereof can be enhanced (made higher) up to at least an input level where the solid line B3 and the dotted line L intersect each other. Therefore, according to the speaker system I of the present embodiment, even when a large gain value is set at the Over_Drive block 14a and/or the Gain block 14b (in the high gain setting), signals in a low band range can be outputted with sufficient sound pressure from the low-pitched sound enhancement section 150 (i.e., the Low_Boost block 14c). Also, the intersection between the solid line B3 and the dotted line L is located below the critical output level (CLIP), such that sounds in a low band range enhanced by the low-pitched sound enhancement section 150 would not be distorted at the power amplifier 106. Therefore, even when the user sets the speaker system 1 at the “high gain setting” for the purpose of intentionally distorting sounds, sounds in a low band range can be favorably enhanced and outputted from the speaker 101.

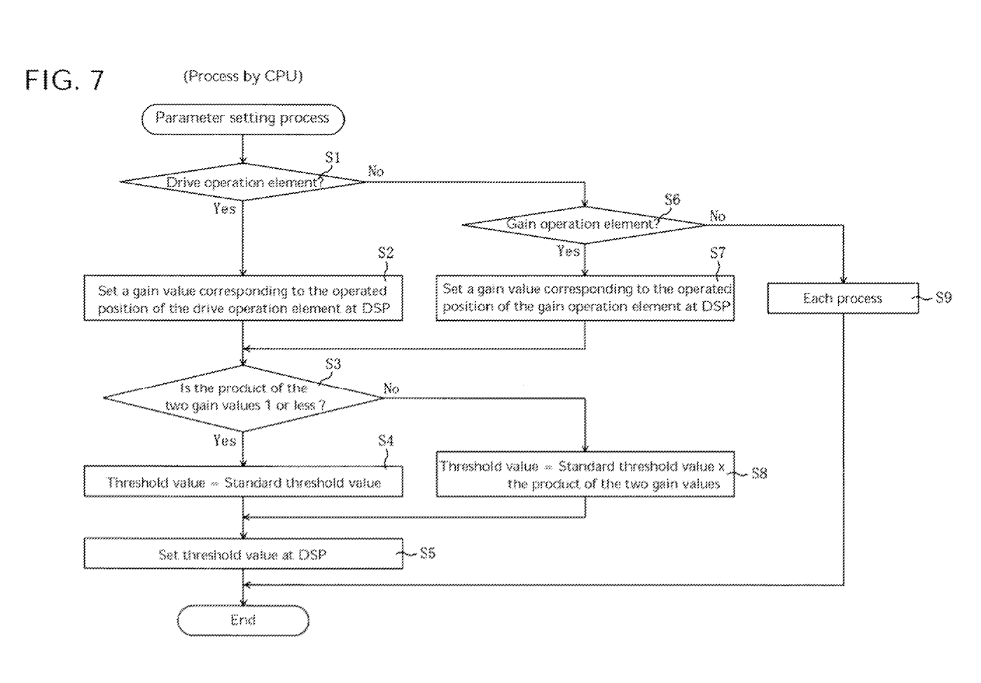

Next, referring to FIG. 7, an example is described of a process of the CPU 11 of the control device 105 to control the threshold value according to the operated positions of the drive operation element 104c and the gain operation element 104d (in other words, the respective gain values set by the operation elements 104c and 104d). FIG. 7 is a flow chart showing an example of a parameter setting process executed by the CPU 11. The CPU 11 monitors the state of each of the operation elements 104c-104h provided at the operation panel 104, and executes the parameter setting process when any one of the operation elements 104c-104h is operated.

The CPU 11 first judges as to whether or not an operation element that is operated is the drive operation element 104c (S1). If the judgment in S1 indicates that the drive operation element 104c is operated (S1: Yes), the CPU 11 obtains a gain value of the Over_Drive block 14a corresponding to the operated position of the drive operation element 104c, stores the obtained gain value in the RAM 13 and sets the same at the DSP 14 (S2). The process then proceeds to S3. It is noted that the gain value stored in the RAM 13 will be retained until it is updated in S2 at a later time.

On the other hand, if the judgment by S1 indicates that the drive operation element 104c is not operated (S1: No), it is judged as to whether or not the operated operation element is the gain operation element 104d (S6). If the judgment in S6 indicates that the gain operation element 104d is operated (S6: Yes), the CPU 11 obtains a gain value of the Gain block 14b corresponding to the operated position of the gain operation element 104d, stores the obtained gain value in the RAM 13 and sets the same at the DSP 14 (S7). The process then proceeds to S3. The gain value stored in the RAM 13 will be retained until it is updated in S7 at a later time.

In S3, the CPU 11 judges as to whether or not the product of the gain value stored in the RAM 13 in S2 (the gain value corresponding to the operation of the drive operation element 104c) and the gain value stored in the RAM 13 in S6 (the gain value corresponding to the operation of the gain operation element 104d) is 1 or less (S3). If the judgment by S3 indicates that the product of the gains is 1 or less (S3: Yes), the CPU 11 sets, as a threshold value, a standard threshold value (for example, a threshold value determined at the time of manufacture, in a manner that the degree of enhancement of sounds in a low band range becomes favorable according to gain values set at the Over_Drive block 14a and the Gain block 14b at the time of manufacture) (S4). The process then proceeds to S5.

On the other hand, if the judgment by S3 indicates that the product of the gains is greater than 1 (S3: No), which means a high gain setting, the CPU I 1 sets, as a threshold value, a value obtained by multiplying the product of the two gain values by the standard threshold value (S8). The process then proceeds to S5.

In S5, the CPU 11 sets the threshold value set in S4 or S8 at the DSP 14 (S5), and ends the parameter setting process. Also, if the judgment by S6 indicates that the gain operation element 104d is not operated (S6: No), then one of the operation elements 104e-104h is operated. Therefore the CPU 11 executes the processes (each process) according to the operated operation element (S9), and ends the parameter setting process.

As described above, when a speaker system 1 in accordance with example embodiments of the invention is used with the ordinary gain values being set (in the ordinary setting) and when it is used with greater gain values set for the purpose of intentionally distorting sounds (in the high gain setting), sound pressure in a low band range can be favorably enhanced according to the purpose intended by the user, and insufficiency of sound pressure in a low band range can be prevented. Also, the speaker system 1 is configured to prevent insufficiency of sound pressure in a low band range at the high gain setting, by changing the threshold value of the compressor 143, such that the sound quality would not be deteriorated.

Furthermore, in a speaker system 1 in accordance with example embodiments of the invention, the Over Drive block 14a and the Gain block 14b which have large input/output level ratios (gains) are placed in a preceding stage of the Low_Boost block 14c. Accordingly, noise that could be generated by the Low_Boost block 14c can be prevented from being enhanced by the blocks 14a and 14b.

It is noted that the signal level outputted (output level) from a bass differs depending on the type of bass. As described above, the Low_Boost block 14c of example embodiments of the invention changes the degree of enhancement (degree of accentuation) of sounds in a low band range, according to the magnitude of the signal level inputted in the block 14c. However, typically, the user would adjust the gain operation element 104d in line with the output level of signals from the bass. Therefore, by placing the Low_Boost block 14c in a succeeding stage of the Gain block 14b, the level of signals inputted in the Low_Boost block 14c becomes constant regardless of the output level of signals from the bass.

For a bass-reflex type speaker system, the frequency band to be enhanced by passing through the low-pitched sound enhancement section 150 may be a frequency band that includes a resonance frequency of the bass-reflex port 102. When the frequency band to be processed by the low-pitched sound enhancement section 150 is a frequency band that includes a resonance frequency of the bass-reflex port 102, generation of whistling sound can be suppressed when signals at a high level are inputted, because the resonant frequency in the suppressed band will be suppressed.

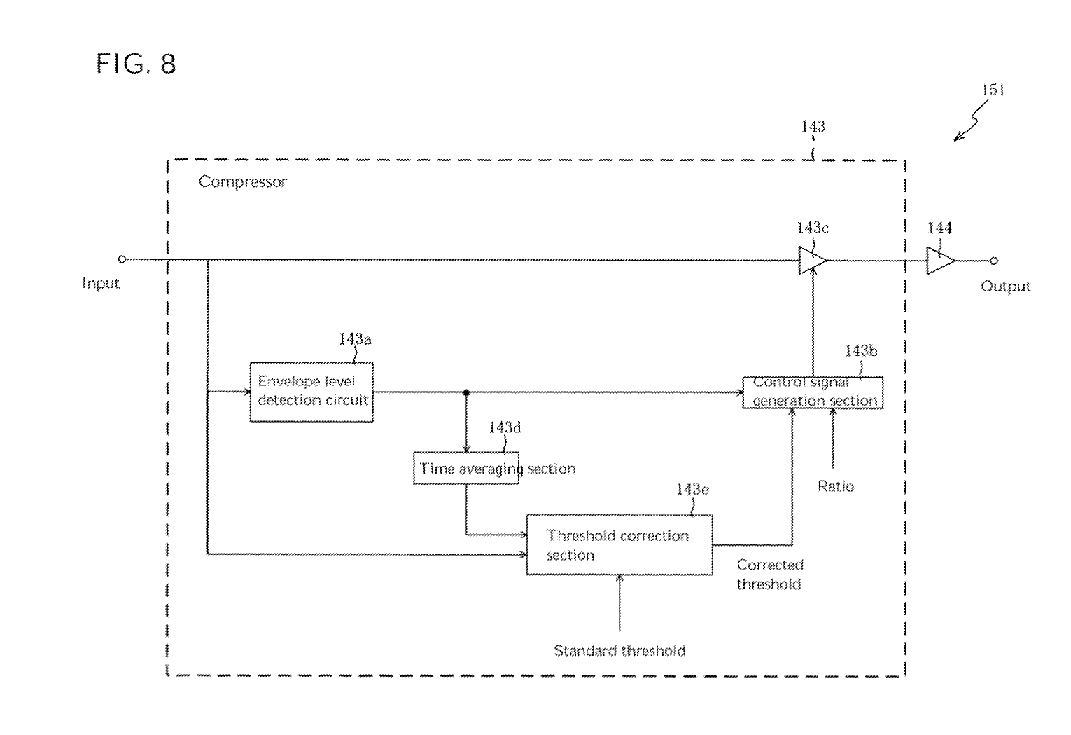

Further example embodiments of a low-pitched sound enhancement processing apparatus are described with reference to FIG. 8. Example embodiments described above are configured in a manner such that the threshold value that is set at the compressor 143 (the control signal generation section 143b) is changed (raised), based on the operated positions of the drive operation element 104c and the gain operation element 104d. Accordingly, even when the presumed maximum level of input signals is exceeded, sounds in a low band range can be outputted with sufficient sound pressure. In contrast, in accordance with further example embodiments, the signal level inputted in the low-pitched sound enhancement processing section 150 is monitored, and a threshold value is dynamically controlled according to the input level. It is noted that portions of the further example embodiments that are the same as those of the above-discussed example embodiments are provided with the same reference numbers, and reference is made to the descriptions provided above for those portions.

FIG. 8 is a functional block diagram schematically showing a flow of a process executed by a low-pitched sound enhancement section 151 in accordance with the further example embodiments. The low-pitched sound enhancement section 151 in accordance with the further example embodiments includes a compressor 143′ in a preceding stage and a multiplier 144 in a succeeding stage, similar to that described above with respect to the low-pitched sound enhancement section 150 in the above-described example embodiments (see FIG. 5). However, the compressor 143′ includes a time averaging section 143d and a threshold correction section 143e, in addition to the functions 143a-143c of the low-pitched sound enhancement section 150 described above.

As shown in FIG. 8, a signal inputted to the compressor 143′ is supplied to an envelope level detection section 143a and a multiplier 143c. The envelope level detection section 143a detects an envelope level of the signal, as described with respect to the above example embodiments. The envelope level detected (at a current time) by the envelope level detection section 143a is supplied to the control signal generation section 143b and the time averaging section 143d.

The time averaging section 143d calculates an average of envelope levels in the latest predetermined time period (for example, five seconds), thereby calculating a time-averaged envelope level. The time-averaged envelope level calculated by the time averaging section 143d is supplied to the threshold correction section 143e.

The threshold correction section 143e corrects the standard threshold value (a threshold value determined at the time of manufacture) based on the envelope level (the time-averaged envelope level) inputted from the time averaging section 143d, thus calculating a corrected threshold value. More specifically, the standard threshold value is multiplied by a quotient obtained by dividing the envelope level inputted from the time averaging section 143d by a predetermined level, thus calculating the corrected threshold value. The corrected threshold value calculated by the threshold correction section 143e is supplied to the control signal generation section 143b.

The control signal generation section 143b generates a control signal for level control based on the envelope level inputted from the envelope level detection section 143a, the corrected threshold value inputted from the threshold correction section 143e, and the ratio value set by the CPU 11. The control signal for level control is supplied to a multiplier 143c. The multiplier 143c controls the level of the input signal in accordance with the control signal for level control supplied from the control signal generation section 143b. The signal outputted from the multiplier 143c (the input signal with its level being controlled) is supplied to the multiplier 144.

As described above, in the Low_Boost block 14c having the low-pitched sound enhancement section 151 in accordance with the further example embodiments, when the signal level in a low band range inputted in the low-pitched sound enhancement section 151 is greater than the predetermined level for a certain period of time, the corrected threshold value is set greater than the standard threshold value. Furthermore, the greater the level difference therebetween, the greater the corrected threshold value becomes. Therefore, when the signal level inputted in the low-pitched sound enhancement section 151 is high (for example, higher than the presumed maximum level of input signals), the output level from the low-pitched sound enhancement section 151 can be prevented from becoming smaller than the input level, and therefore insufficiency in the sound pressure in a low band range can be prevented. In other words, even when the signal level inputted in the low-pitched sound enhancement section 151 is high, sounds in a low band range can be outputted with sufficient sound pressure.

In addition, when the signal level in a low band range inputted in the low-pitched sound enhancement section 151 is smaller than the predetermined level for a certain period of time, the corrected threshold value is set smaller than the standard threshold value. Furthermore, the greater the level difference therebetween, the smaller the corrected threshold value becomes. When the input level of signals inputted in the low-pitched sound enhancement section 151 is always smaller than the threshold value because the level of signals outputted from a bass (signals inputted in the input terminal 104b) is smaller, or some other reasons, sounds in a low band range may be excessively enhanced. However, in accordance with the further example embodiments, when the time-averaged envelope level is smaller than the predetermined level, the threshold level can be lowered, such that the excessive enhancement of sounds in a low band range described above can be prevented.

While the invention has been described above based on example embodiments, the invention is not limited to those example embodiments, and it can readily be surmised that many modifications and improvements can be made without departing from the subject matter of the invention.

For example, some example embodiments described above are configured in a manner that, when the product of gain values set respectively by the drive operation element 104c and the gain operation element 104d is 1 or less, the CPU 11 sets the standard threshold Value at the DSP 14 (at the control signal generation section 143b of the compressor 143). In other words, in accordance with those example embodiments, when the product of gain values set by the drive operation element 104c and the gain operation element 104d is 1 or less, the threshold value of the compressor 104c is constant. Instead, when the product of gain values set by the drive operation element 104c and the gain operation element 104d is less than 1, the CPU 11 may control the threshold value of the compressor 143, and may make the threshold value smaller than the standard threshold value, similar to the further example embodiments described above.

For example, the procedures of S3 and S4 in the parameter setting process shown in FIG. 7 may be omitted, and the CPU 11 may execute the process in S8, after executing the process in S2 or S7. Accordingly, the threshold value may be calculated by “the standard threshold value” multiplied by “the product of the gain values,” such that the threshold value of the compressor 143 can be set to a value smaller than the standard threshold value, for not only the case where the product of a gain value set by the drive operation element 104c and a gain value set by the gain operation element 104d is greater that 1 (a first mode), but also for the case where it is less than 1.

In that example, when the product of the two gain values is 1, the threshold value is set to the standard threshold value, and when the product of the two gain values is less than 1, the threshold value is set to a value smaller than the standard threshold value. However, the threshold at which the threshold value is to be lowered may be set at a value other than 1, such that the range in using the standard threshold value may be widened. More specifically, for example, the threshold at which the threshold value is to be lowered may be set at 0.8, such that when the product of the two gain values is in the range between 0.8 and 1, the threshold value may be set to the standard threshold value; and when the product of the two gain values is less than 0.8, the threshold value may be set to a value smaller than the standard threshold value.

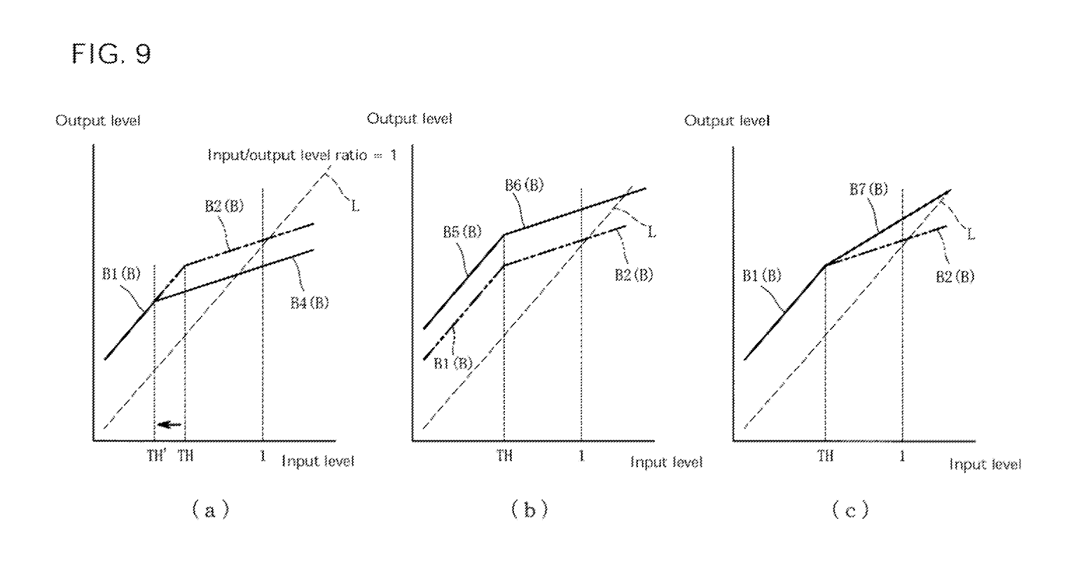

FIG. 9(a) is a graph representing input/output characteristics of the low-pitched sound enhancement section 150 when the threshold value of the compressor 143 is lowered. In this graph, the horizontal axis represents, in logarithmic scale, input levels of signals inputted in the low-pitched sound enhancement section 150. The vertical axis represents, in logarithmic scale, output levels of signals outputted from the low-pitched sound enhancement section 150.

When the product of gain values set respectively by the drive operation element 104c and the gain operation element 104d (i.e., the product of the two gain values) is less than 1, the threshold value of the compressor 143 is lowered from TH (the standard threshold value) to TH′. Due to the change of the threshold value from TH to TH′, a bent line B composed of two lines (a solid line or a two-dot-and-dash line B1 and a two-dot-and-dash line B2) with TH being a threshold value is changed to a bent line B composed of two lines (a solid line B1 and a solid line B4) with TH′ being a threshold value. As described above, when the input level of signals inputted in the low-pitched sound enhancement section 150 is always smaller than the threshold value of the compressor 143, then sounds in a low band range can be excessively enhanced. However, by lowering the threshold value according to the product of the gain values set by the respective operation elements 104c and 104d, such excessive enhancement of sounds in the low band range can be prevented. Embodiments can be configured such that the change of the threshold value may be executed only in the lowering direction when the product of the two gain values is less than a predetermined value, while omitting the change in the raising direction that would otherwise be made according to certain embodiments described above.

Also, in certain example embodiments described above, the threshold value of the compressor 143 is changed according to the product of gain values set by the respective operation elements 104c and 104d, and the threshold at which the threshold value is to be changed is set to 1 (“the product of the two gain values”=1). However, in other embodiments, the threshold is not limited to “1,” and any suitable value can be suitably used according to the design of the speaker system 1. For example, in the parameter setting process shown in FIG. 7, the process in S3 may be configured such that the CPU 11 judges as to whether or not the product of the two gain values is less than 1.2 (or other suitable value). Similarly, in further example embodiments described above, the threshold correction section 143e may be configured such that the divisor (i.e., the value of the predetermined level) for dividing the time-averaged envelope level may be selectively changed, such that the threshold for changing the threshold value can be selectively changed.

Further, embodiments configured in a manner that the threshold value can be raised and lowered like the modification example described above, the threshold (the product of the two gain values) at which the threshold value is to be raised, and the threshold at which the threshold value is to be lowered may be set at different values. For example, the threshold for raising the threshold value may be set at 1.0, and the threshold for lowering the threshold value may be set at 0.8. Accordingly, when the product of the two gain values is greater than 1, the threshold value of the compressor 143 becomes greater than the standard threshold value; when the product of the two gain values is between 0.8 and 1, the threshold value of the compressor 143 becomes equal to the standard threshold value; and when the product of the two gain values is less than 0.8, the threshold value becomes smaller than the standard threshold value. Other suitable thresholds may be used for other embodiments.

Also, in accordance with certain example embodiments described above, the threshold value is calculated by “the standard threshold value” multiplied by “the product of the two gain values” according to the product of gain values set by the respective operation elements 104c and 104d. However, other embodiments are not limited to the aforementioned formula, and any other suitable formulas may be used to calculate the threshold value. For example, a value obtained by squaring the product of the two gain values may be multiplied with the standard threshold value. Also, in calculating the product of the gain values respectively set by the operation elements 104c and 104d, each of the gain values may be squared, and the product of the these squared gain values may be used as the product for threshold value calculation.

Also, certain example embodiments described above are configured such that a threshold value is obtained according to the product of gain values set respectively by the operation elements 104c and 104d. However, a table defining the relation between “products of two gain values” and threshold values, a table defining the relation between input levels and threshold values or the like may be prepared in advance, and the table may be referred to, based on the product of two gain values, to determine a threshold value. In this case, unlike certain example embodiments described above, in which the threshold is changed from the reference threshold according to a predetermined value of the product of two gain values, the threshold can be determined directly according to two gain values set respectively by the operation elements 104c and 104d and an input level. For example, a table that defines thresholds with gradually greater values set accordingly for input levels with gradually greater values, and defines thresholds with gradually smaller values set accordingly for input levels with gradually smaller values may be prepared, such that the threshold can be determined directly according to the input level. In the table defining the relation between “products of two gain values” or input levels and threshold values, the threshold values may be increased continuously or in stepwise with respect to an increase in the “product of the two gain values” or in the input level.

Also, in accordance with further example embodiments described above, when the quotient obtained by dividing a time-averaged envelope level by a predetermined level is less than 1, the standard threshold value may be set as the corrected threshold value to be supplied to the control signal generation section 143b, without multiplying the quotient with the standard threshold value. Thus, only when the time-averaged envelope level is greater than the predetermined level, the threshold value can be raised. Conversely, embodiments may be configured such that, when the quotient is greater than 1, the standard threshold value may be set as the corrected threshold value without multiplying the quotient with the standard threshold value, such that the threshold value may be lowered only when the time-averaged envelope level is smaller than the predetermined level. Also, any suitable alternative formula (as described above or otherwise) may be used to calculate a corrected threshold value. For example, “the quotient obtained by dividing a time-averaged envelope level by a predetermined level” may be squared, and the obtained value may be multiplied with the standard threshold value to calculate a corrected threshold value. Also, the divisor used for dividing a time-averaged envelope level may be, for example, a value obtained by squaring the predetermined level.

In accordance with certain example embodiments described above, in the high gain setting (when the product of gain values set respectively by the operation elements 104c and 104d is greater than 1), the threshold value of the compressor 143 is made greater than the standard threshold value, such that insufficiency in the sound pressure in a low band range can be prevented even when the level of signals inputted in the low-pitched sound enhancement section 150 is high (see FIG. 6(C)). Instead, yet further embodiments can be configured such that, in the high gain setting, the input/output level ratio (gain) with respect to an input level greater than the threshold value may be made greater than that in the standard setting. For example, in the high gain setting, the control signal for level control generated by the control signal generation section 143b may use a value obtained by multiplying a value in the standard setting with a predetermined gain value for raising the input/output level ratio. Alternatively, a gain value set at a multiplier independent of the multiplier 144 or the multiplier 144 may be set at 1 in the normal gain setting, and a value greater than 1 in the high gain setting. In this case, the multiplier independent of the multiplier 144 may be provided in a preceding stage or in a succeeding stage of the compressor 143.

FIG. 9(b) is a graph representing input/output characteristics of the low-pitched sound enhancement section 150 in accordance with the modified example described above. In this graph, the horizontal axis represents, in logarithmic scale, input levels of signals inputted in the low-pitched sound enhancement section 150. The vertical axis represents, in logarithmic scale, output levels of signals outputted from the low-pitched sound enhancement section 150. A bent line B composed of a two-dot-and-dash line B1 below TH and a two-dot-and-dash line B2 above TH represents input/output characteristics when the product of gain values set respectively by the operation elements 104c and 104d is 1 or less (in the normal setting). When the product of gain values set respectively by the operation elements 104c and 104d is greater than 1 (in the high gain setting), the input/output level ratio may be made greater than that in the normal setting, such that the input/output characteristics represented by the bent line B composed of the two-dot-and-dash lines B1 and B2 are changed to those represented by a bent line B composed of solid lines B5 and B6. By this change, at levels greater than the presumed maximum level of input signals, the solid line B6 and the dotted line L intersect each other. Accordingly, even for an input signal at a level greater than the presumed maximum level of input signals, the level of the input signal can be enhanced and outputted, similar to the case where the threshold value is changed (similar to certain example embodiments described above).

Alternatively, in the high gain setting, the ratio at the compressor 143 (the control signal generation section 143b) for input levels greater than the threshold value may be set such that the inclination of input/output characteristics becomes greater than that in the standard setting.

FIG. 9(c) is a graph representing input/output characteristics of the low-pitched sound enhancement section 150 in accordance with a modified example as described above. In this graph, the horizontal axis represents, in logarithmic scale, input levels of signals inputted in the low-pitched sound enhancement section 150. The vertical axis represents, in logarithmic scale, output levels of signals outputted from the low-pitched sound enhancement section 150. A bent line B composed of a solid line B1 below TH and a two-dot-and-dash line B2 above TH represents input/output characteristics in the normal setting. In the high gain setting, the ratio of the compressor 143 may be set such that the inclination of input/output characteristics becomes greater than that in the standard setting. As a result, the two-dot-and-dash line B2 above TH in the bent line B is changed to a solid line B7 with a greater inclination than that of the line B2. By this change, at levels greater than the presumed maximum level of input signals, the solid line B7 and the dotted line L intersect each other. Accordingly, even for an input signal at a level greater than the presumed maximum level of input signal, the level of the input signal can be enhanced and outputted, similar to the case where the threshold value is changed (similar to certain example embodiments described above).

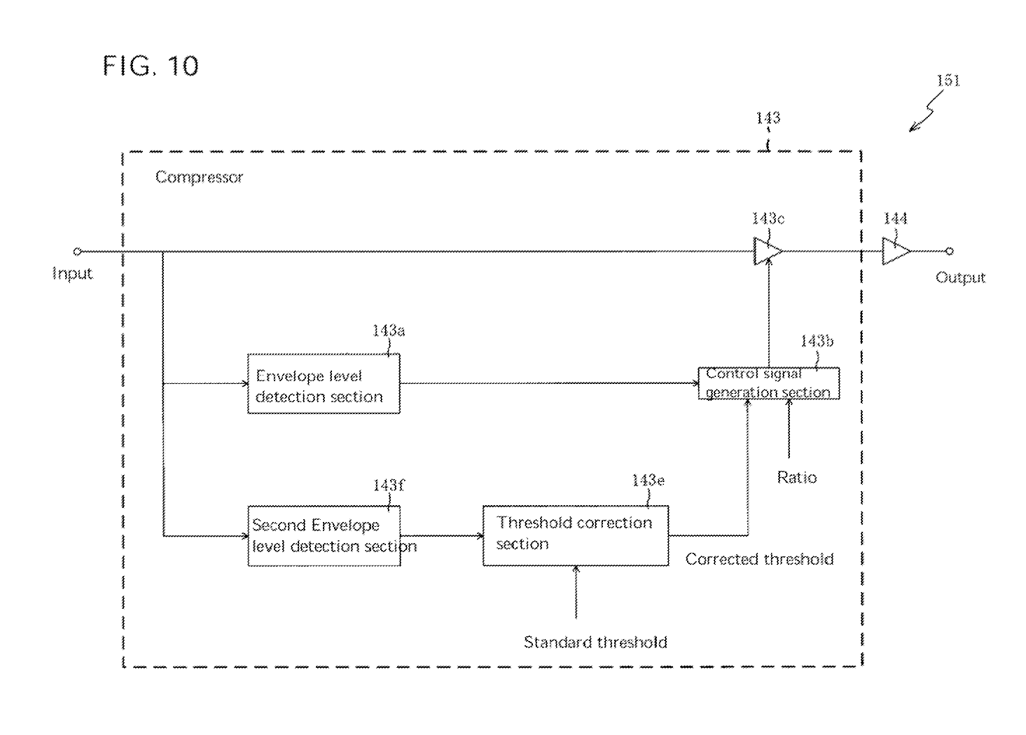

Also, in accordance with further example embodiments described above, as shown in FIG. 8, an envelope level is detected by the envelope level detection section 143a, the envelope level is time-averaged by the time averaging section 143d, and the standard threshold value is corrected based on the time-averaged envelope level. However, other methods for correcting the standard threshold value may be used and are not limited to the examples described above. For example, as shown in FIG. 10, an envelope level detection section independent of the envelope level detection section 143a may be provided, and the standard threshold value may be corrected based on an envelope level detected by the independent envelope level detection section.

FIG. 10 is a functional block diagram schematically showing a flow of an example processes executed by a low-pitched sound enhancement processing section 151 in accordance with a modified example of the further embodiments described above. In FIG. 10, portions that are identical to those of further embodiments described above (with respect to FIG. 8) are provided with the same reference numbers, and reference is made to the descriptions provided above for those portions. The low-pitched sound enhancement section 151 of this modified example is provided with a second envelope level detection section 143f instead of the time averaging section 143d included in the low-pitched sound enhancement section 151 of the further example embodiments described above.

As shown in FIG. 10, a signal inputted to the compressor 143 is supplied to an envelope level detection section 143a, a second envelope level detection section 143f, and a multiplier 143c.

The second envelope detection section 143f first obtains an absolute value of an instantaneous value of the input signal. If that obtained absolute value is greater than a previous envelope level (a value detected last time by the second envelope detection section 1430f) stored in the RAM 13, then the second envelope detection section 143f stores a value obtained by making the previous envelope level asymptotic to a predetermined first time constant with the obtained absolute value as a target value in the RAM 13 (the RAM 13 is rewritten). On the other hand, if the obtained absolute value is smaller than that of a previous envelope level stored in the RAM 13, then a value obtained by attenuating the previous envelop level by a predetermined second time constant is stored in the RAM 13 as an envelope level this time. It is noted that the second time constant may be set slower than the first time constant, and set slower than the time constant used for attenuating the envelope level by the envelope level detection section 143a. By executing the process described above at the second envelope level detection section 143f, a quasi-time-averaged envelope level can be detected.

The quasi time-averaged envelope level detected (at a current time) by the second envelope level detection section 143f is supplied to the threshold correction section 143e. The threshold correction section 143e corrects the standard threshold value based on the envelope level (quasi-time-averaged envelope level) inputted from the second envelope level detection section 143f, thus calculating a corrected threshold value. More specifically, the standard threshold value is multiplied by a quotient obtained by dividing the envelope level inputted from the second envelope level detection section 143f by a predetermined level, thus calculating the corrected threshold value. The corrected threshold value calculated by the threshold correction section 143e is supplied to the control signal generation section 143b.

In further example embodiments described above (see FIG. 8) or in modified examples thereof (see FIG. 10), when calculating a time-averaged (or a quasi-time-averaged) envelope level, hysteresis characteristic may be given thereto. For example, if the changing direction of the envelope level detected at the current time by the envelope level detection section 143a, with respect to an envelope level detected a previous time, is in the opposite direction to the change direction of previous envelope levels, and the amount of change in the envelope level is less than a predetermined amount, the same value as the previous time may be set as the corrected threshold value. This makes it less likely that time-dependent changes in the envelope level will be reflected on the threshold, such that the sound quality can be made better.

Also, further example embodiments described above (e.g., with respect to FIG. 8) may be configured such that changes in the input/output level ratio as shown in FIG. 9(b) and changes in the ratio as shown in FIG. 9(c) may be made, based on the time-averaged envelope level. Also, in certain example embodiments described above (where the input/output characteristics are changed based on operated positions of the respective operation elements 104c and 104d) and in further example embodiments described above (where the input/output characteristics are dynamically changed based on the level of an input signal), in the high gain setting, the change of the threshold value, change of the input/output level ratio and change of the ratio may be suitably combined.

Further, in each of the embodiments described above, the frequency of signals to be inputted to and enhanced by the low-pitched sound enhancement section 150 in the Low_Boost block 14c is set at 100 Hz or less. However, in further embodiments, that frequency range may be set at any other suitable level, for example, but not limited to, 200 Hz or less.

Also, in each of the embodiments described above, the channel divider 141 is configured to divide input signals into two channels. However, in further embodiments, frequency bands to be divided may be divided into two channels or more, if at least one of the channels is in a low band range.

It is noted that, if input signals are divided by the channel divider 141 into three channels or more, and two or more channels thereof are frequency bands belonging to low band ranges, it is not necessary to perform enhancement by the low-pitched sound enhancement section 150 for all of the frequency bands in the low band ranges. Instead, at least one of the frequency bands is enhanced by the low-pitched sound enhancement section 150.

For example, input signals may be divided by the channel divider 141 into three channels, i.e., a high band range, a first low band range and a second low band range that is lower than the first low band range. In this case, among the two bands (the first low band range and the second low band range) belonging to a low band range, the first low band range or the second low band range, alone, may be inputted in the low-pitched sound enhancement section 150 and enhanced.

Also, for example, in the case of dividing signals into three channels as described above, the low-pitched sound enhancement section 150 may be provided for each of the first low band range and the second low band range, and signals in each of the band ranges may be inputted in and enhanced by each of the low-pitched sound enhancement sections, respectively. In this case, the degree of enhancement (for example, the value of the threshold and the value of the ratio) by the low-pitched sound enhancement section 150 corresponding to each of the frequency bands may be made different for each of the frequency bands.

Also, in each of the embodiments described above, the Low_Boost block 14c is configured to have the multiplier 144 in a succeeding stage of the compressor 143. However, further embodiments may be configured to have the multiplier 144 provided in a preceding stage and the compressor 143 in a succeeding stage, or to have multipliers before and after the compressor 143.

Also, each of the embodiments described above is configured such that, in a preceding stage of the Low_Boost block, the Over_Drive block 14a and the Gain block 14b are provided. In further embodiments, only the Gain block 14b may be provided in such a preceding stage. In this case, the threshold value may be changed according to the gain value set by the gain operation element 104d. For example, the threshold value may be calculated by “the standard threshold value” multiplied by “the gain value set by the gain operation element 104d.”

Alternatively, in addition to the Over_Drive block 14a and the Gain block 14b, one or more other blocks may be provided for elevating the level of signals to be inputted in the Low_Boost block 14c. In this case, for example, the threshold value may be calculated by “the standard threshold value” multiplied by “the product of gains values set at the respective blocks.”

Also, each of the embodiments described above is configured such that, when the gain value set by the gain operation element 104d is greater than 1, the Gain block 14b raises the input/output level ratio for passing signals and also generates distortion therein. However, other embodiments can be configured to raise the input/output level ratio for passing signals without generating distortion therein.

Also, in each of the embodiments described above, the speaker system 1 is described as a bass-reflex type speaker system. However, a sealed enclosure type speaker system may be configured with embodiments of the present invention, including a Low_Boost block 14c (the low-pitched sound enhancement section 150).

Also, in each of the embodiments described above, functions of the Low_Boost block 14c are provided by the control device 105 of the speaker system 1 having the power amplifier 106. However, in other embodiments, functions of the Low_Boost block 14c may be provided by an independent apparatus that is connected to a power amplifier or a speaker system having a power amplifier. An independent apparatus provided with the function of the Low_Boost block 14c may also be provided with functions to add effects, such as, the Over_Drive block 14a, the Chorus block 14e, the Reverb block 14f and the like. In this case, like the embodiments described above, the Over_Drive block 14a may be disposed in a preceding stage of the Low_Boost block 14c.

Further, in each of the embodiments described above, the terminal to be connected to the input terminal 104b of the speaker system 1 is an output terminal of a bass. In other embodiments, an output of an effector connected to a bass is connected to the input terminal 104b.

Also, in each of the embodiments described above, a bass is an example of a string musical instrument that is connected to the speaker system 1. However, in other embodiments, any string musical instruments capable of outputting sounds in a low band range can favorably benefit from the enhancement of sounds in a low band range by the Low_Boost block 14c (the low-pitched sound enhancement section 150). Also, in each of the embodiments described above, functions of each of the blocks 14a-14g are provided by digital processing by the DSP 14. However, in other embodiments, other suitable circuits, including analog circuits, may be employed to provide functions of one or more of the blocks 14a-14g.

1. A low-pitched sound enhancement processing apparatus comprising:
an input device for receiving an input musical sound signal that is based on performance of a stringed musical instrument capable of generating sounds in a low band range;
a band divider device that divides the input musical sound signal received by the input device, or divides a musical sound signal that has been generated by adding a predetermined effect to the input musical sound signal received by the input device, into a plurality of frequency bands of the musical sound signal; and
a low-pitched sound enhancement processing device that inputs and enhances musical sound signals in at least one of the frequency bands of a low band range as divided by the band divider device, and outputs an enhanced musical sound signal for the at least one frequency band;
wherein the low-pitched sound enhancement processing device has a compression device that compresses musical sound signals higher than a predetermined level with a predetermined compression characteristic; and
an enhancement device preceding and/or succeeding the compression device, that enhances the musical sound signals;
wherein the low-pitched sound enhancement processing device enhances musical sound signals through compression by the compression device and enhancement by the enhancement device; and
the low-pitched sound enhancement processing apparatus further includes a control device that controls compression by the compression device and/or enhancement by the enhancement device such that an input/output level ratio of the low-pitched sound enhancement processing device is determined at least in part based on the input level of musical sound signals inputted in the low-pitched sound enhancement processing device.

2. A low-pitched sound enhancement processing apparatus as recited in claim 1, wherein the control device controls compression by the compression device and/or enhancement by the enhancement device, such that the input/output level ratio of the low-pitched sound enhancement processing device becomes greater with an elevation in the input level of musical sound signals inputted to the low-pitched sound enhancement processing device.

3. A low-pitched sound enhancement processing apparatus as recited in claim 1, wherein:
the compression device performs compression of musical sound signals, using the predetermined level as a threshold, with a compression characteristic of compressing a musical sound signal greater than the predetermined level to a greater degree than a musical sound signal at or below the predetermined level; and
the control device controls, based on the input level of musical sound signals inputted to the low-pitched sound enhancement processing device, the predetermined level set as the threshold for the compression device, such that the threshold becomes greater, continuously or in stepwise, with elevation in the input level, to increase the input/output level ratio of the low-pitched sound enhancement processing device.

4. A low-pitched sound enhancement processing apparatus as recited in claim 1, further comprising a gain setting device that sets a value of a gain, and an input level adjusting device that adjusts the input level of musical sound signals inputted to the low-pitched sound enhancement processing device, based on the value of the gain set by the gain setting device, wherein the control device controls compression by the compression device and/or enhancement by the enhancement device, based on the value of a gain set by the gain setting device, such that the input/output level ratio of the low-pitched sound enhancement processing device becomes greater, continuously or in stepwise, with an elevation in the input level of musical sound signals inputted to the low-pitched sound enhancement processing device.

5. A low-pitched sound enhancement processing apparatus as recited in claim 1, further comprising a monitoring device that monitors time-dependent changes in the input level of musical sound signals inputted to the low-pitched sound enhancement processing device, wherein the control device controls compression by the compression device and/or enhancement by the enhancement device, based on the time-dependent changes in the input level monitored by the monitoring device, such that the input/output level ratio of the low-pitched sound enhancement processing device becomes greater, continuously or in stepwise, with an elevation in the input level of musical sound signals inputted to the low-pitched sound enhancement processing device.

6. A low-pitched sound enhancement processing apparatus recited in claim 1, characterized in that the stringed musical instrument is a bass.

7. A speaker system for a musical instrument, the speaker system comprising the low-pitched sound enhancement processing apparatus recited in claim 1; a power amplifier provided in a succeeding stage of the low-pitched sound enhancement processing apparatus; and a speaker for emanating an output from the power amplifier.

8. A speaker system for a musical instrument as recited in claim 7, further comprising a housing having an inner space, the housing supporting the low-pitched sound enhancement processing apparatus, the power amplifier and the speaker, the housing having an opening section for bass reflex, the opening section including at least one opening connecting the interior space of the housing with space external to the housing, wherein the frequency band processed by the low-pitched sound enhancement processing device is a band including a resonance frequency of the opening section for bass-reflex.

9. A speaker system for a musical instrument recited in claim 8, further comprising at least one effects device provided in a preceding stage relative to the low-pitched sound enhancement processing apparatus and having a pass gain greater than 1 for adding an effect to musical sound signals.

10. A sound effects apparatus comprising the low-pitched sound enhancement processing apparatus recited in claim 1; and at least one effects device provided in a preceding stage relative to the low-pitched sound enhancement processing apparatus, and having a pass gain greater than 1 for adding an effect to musical sound signals.

11. A low-pitched sound enhancement processing apparatus comprising
a processing device that inputs and enhances musical sound signals in at least one frequency band of a low band range and outputs an enhanced musical sound signal for the at least one frequency band, the processing device having an input/output level ratio determined by a level of the musical sound signals input to the processing device and a level of the enhanced musical sound signals output from the processing device, the processing device including:
a compression device that compresses musical sound signals higher than a predetermined level with a predetermined compression characteristic, and
an enhancement device preceding and/or succeeding the compression device, that enhances the musical sound signals; and
a control device that controls compression by the compression device and/or enhancement by the enhancement device such that the input/output level ratio of the processing device is determined, at least in part, based on the input level of musical sound signals inputted in the processing device.

12. A low-pitched sound enhancement processing apparatus as recited in claim 11, wherein the control device controls compression by the compression device and/or enhancement by the enhancement device, such that the input/output level ratio of the processing device becomes greater with an elevation in the input level of musical sound signals inputted to the processing device.

13. A low-pitched sound enhancement processing apparatus as recited in claim 11, wherein:
the compression device performs compression of musical sound signals, using the predetermined level as a threshold, with a compression characteristic of compressing a musical sound signal greater than the predetermined level to a greater degree than a musical sound signal at or below the predetermined level; and
the control device controls, based on the input level of musical sound signals inputted to the processing device, the predetermined level set as the threshold for the compression device, such that the threshold becomes greater, continuously or in stepwise, with elevation in the input level, to increase the input/output level ratio of the processing device.

14. A low-pitched sound enhancement processing apparatus as recited in claim 11, further comprising a gain setting device that sets a value of a gain, and an input level adjusting device that adjusts the input level of musical sound signals inputted to the processing device based on the value of the gain set by the gain setting device, wherein the control device controls compression by the compression device and/or enhancement by the enhancement device, based on the value of a gain set by the gain setting device, such that the input/output level ratio of the processing device becomes greater, continuously or in stepwise, with an elevation in the input level of musical sound signals inputted to the processing device.

15. A low-pitched sound enhancement processing apparatus as recited in claim 11, further comprising a monitoring device that monitors time-dependent changes in the input level of musical sound signals inputted to the processing device, wherein the control device controls compression by the compression device and/or enhancement by the enhancement device, based on the time-dependent changes in the input level monitored by the monitoring device, such that the input/output level ratio of the processing device becomes greater, continuously or in stepwise, with an elevation in the input level of musical sound signals inputted to the processing device.

16. A method of enhancing low-pitched sound, the method comprising
inputting musical sound signals that include at least one frequency band of a predefined band range;
enhancing, in a processing device, inputted musical sound signals in the least one frequency band and outputting enhanced musical sound signals for the at least one frequency band, the processing device having an input/output level ratio determined by a level of the inputted musical sound signals and a level of the enhanced musical sound signals, the enhancing including:
compressing inputted musical sound signals that are higher than a predetermined level with a predetermined compression characteristic, and
enhancing the musical sound signals before and/or after compressing the musical sound signals; and
controlling compression by the compression device and/or enhancement by the enhancement device such that the input/output level ratio of the processing device is determined at least in part based on the input level of the inputted musical sound signals.

17. A method as recited in claim 16, wherein controlling comprises controlling compression and/or enhancement such that the input/output level ratio of the processing device becomes greater with an elevation in the input level of musical sound signals inputted to the processing device.

18. A method as recited in claim 16, wherein:
compressing comprises defining a predetermined level as a threshold, and compressing a musical sound signal greater than the predetermined level to a greater degree than a musical sound signal at or below the predetermined level; and
controlling comprises controlling the predetermined level set as the threshold, such that the threshold becomes greater, continuously or in stepwise, with elevation in the input level of the musical sound signal, to increase the input/output level ratio of the processing device.

19. A method as recited in claim 16, further comprising setting a gain value, and adjusting an input level of musical sound signals inputted to the processing device based on the set value of the gain, wherein controlling comprises controlling compression and/or enhancement, based on the set value of the gain, such that the input/output level ratio of the processing device becomes greater, continuously or in stepwise, with an elevation in the input level of musical sound signals inputted to the processing device.

20. A method as recited in claim 16, further comprising monitoring time-dependent changes in the input level of musical sound signals inputted to the processing device, wherein controlling comprises controlling compression and/or enhancement, based on the monitored time-dependent changes in the input level, such that the input/output level ratio of the processing device becomes greater, continuously or in stepwise, with an elevation in the input level of musical sound signals inputted to the processing device.
